(19) United States
(12) Patent Application Publication
(10) Pub. No.: US 2025/0105028 A1
(43) Pub. Date: Mar. 27, 2025

(54) CHEMICAL LIQUID PURIFICATION APPARATUS FOR SEMICONDUCTOR MANUFACTURING

(71) Applicant: SAMSUNG ELECTRONICS CO., LTD., Suwon-si (KR)

(72) Inventors: Hee Jeong PARK, Suwon-si (KR); Jihyun KIM, Seoul (KR); Yunho KIM, Suwon-si (KR); Sungjune LEE, Suwon-si (KR); Donggyu LEE, Seoul (KE); Dongryul LEE, Seoul (KR); Sam-Jong Chol, Suwon-si (KR); Kuk Nam HAN, Suwon-si (KR)

(73) Assignees: SANSUNG ELECTRONICS SO., LTD., Suwon-si (KR); SEOUL NATIONAL UNIVERSITY R&DB FOUNDATION, Seoul (KR)

(21) Appl. No.: 18/899,185

(22) Filed: Sep. 27, 2024

(30) Foreign Application Priority Data
Sep. 27, 2023 (KR) 10-2023-0131154
Dec. 6, 2023 (KR) 10-2023-0175935

(51) Int. Cl. H01L 21/67

(52) U.S. Cl. CPC H01L 21/67017

(57) ABSTRACT

Provided is a chemical liquid purification apparatus for semiconductor manufacturing, the apparatus including a first tank configured to store a chemical liquid, the chemical liquid including impurities, a first line configured to supply the chemical liquid to the first tank, a first electrode and a second electrode included in the first tank, an alternating current waveform generator connected to the first electrode and the second electrode, a second line configured to supply the chemical liquid processed in the first tank to an outside of the first tank, and a filter configured to filter the impurities in the chemical liquid flowing in the second line.

### CROSS-REFERENCE TO RELATED APPLICATION

This application claims priority to Korean Patent Application No. 10-2023-0131154, filed on Sep. 27, 2023 and Korean Patent Application No. 10-2023-0175935, filed on Dec. 6, 2023 in the Korean Intellectual Property office, the disclosures of which are incorporated by reference herein in their entireties.

### BACKGROUND

Embodiments of the present disclosure relate to a chemical liquid purification apparatus for semiconductor manufacturing, and more particularly, to a chemical liquid purification apparatus for semiconductor manufacturing which purifies impurities inside the chemical liquid for manufacturing a semiconductor.

As the semiconductor process becomes more refined, impurities, such as extremely small particles and metal ions, are the cause of defects. Filters have been widely used to remove the impurities from various chemical liquids used in semiconductor processes. However, because the improvement of filtration performance does not keep up with the rate of refining the semiconductor process, the development of a new technology that can remove extremely fine-sized impurities from the chemical liquid is required.

### SUMMARY

One or more example embodiments provide a chemical liquid purification apparatus for semiconductor manufacturing, with improved purification efficiency.

In addition, the issues to be solved are not limited to those mentioned above, and other issues may be clearly understood by those of ordinary skill in the art from the following descriptions.

One or more embodiments also provide a chemical liquid purification apparatus for semiconductor manufacturing.

According to an aspect of one or more embodiments, there is provided a chemical liquid purification apparatus for semiconductor manufacturing, the apparatus including a first tank configured to store chemical liquid, the chemical liquid including impurities, a first line configured to supply the chemical liquid to the first tank, a first electrode and a second electrode included in the first tank, an alternating current waveform generator connected to the first electrode and the second electrode, a second line configured to supply the chemical liquid processed in the first tank to an outside of the first tank, and a filter configured to filter the impurities in the chemical liquid flowing in the second line.

According to another aspect of one or more embodiments, there is provided a chemical liquid purification apparatus for semiconductor manufacturing, the apparatus including a first tank configured to store chemical liquid, the chemical liquid including impurities, a first line configured to supply the chemical liquid to the first tank, a first valve and a first pump configured to adjust a flow rate of the chemical liquid flowing in the first line, a first electrode and a second electrode provided apart from each other in the first tank, an alternating current waveform generator configured to provide an alternating current to the first electrode and the second electrode, a second line configured to supply the chemical liquid processed in the first tank to an outside of the first tank, and a second valve and a second pump configured to adjust a flow rate of the chemical liquid flowing in the second line, a filter configured to filter the impurities in the chemical liquid flowing in the second line, a third line connected to the second line, and a second tank connected to the third line.

According to still another aspect of one or more embodiments, there is provided a chemical liquid purification apparatus for semiconductor manufacturing, the apparatus including a first tank configured to store chemical liquid, the chemical liquid including impurities, a first line configured to supply the chemical liquid to the first tank, a first valve and a first pump configured to adjust a flow rate of the chemical liquid flowing in the first line, a first electrode and a second electrode spaced apart from each other in the first tank, an alternating current waveform generator configured to provide an alternating current to the first electrode and the second electrode, a second line configured to supply the chemical liquid processed in the first tank to an outside of the first tank, and a second valve and a second pump configured to adjust a flow rate of the chemical liquid flowing in the second line, a filter configured to filter the impurities in the chemical liquid flowing in the second line, a third line connected to the second line, and a second tank connected to the third line, wherein a diameter of the impurities in the chemical liquid supplied into the first tank in the first line is in a range of 0.5 nm to 20 nm, wherein a diameter of the impurities in the chemical liquid flowing into the second tank is in a range of 100 nm to 5 μm, and wherein the alternating current waveform generator is further configured to apply a voltage in a range of −5 V to 5 V to the first electrode and the second electrode, and an output frequency of the alternating current waveform generator is in a range of 1 kHz to 1000 kHz.

### BRIEF DESCRIPTION OF DRAWINGS

Example embodiments will be more clearly understood from the following detailed description taken in conjunction with the accompanying drawings in which:

FIG. 1 is a diagram of a chemical liquid moving system for semiconductor manufacturing, according to an example embodiment;

FIG. 2 is a diagram of a chemical liquid purification apparatus for semiconductor manufacturing, according to an example embodiment;

FIGS. 3A and 3B are diagrams illustrating an operation of the chemical liquid purification apparatus for semiconductor manufacturing of FIG. 2;

FIG. 4 is a perspective view of an aggregation member according to an example embodiment;

FIG. 5 is a perspective view of an aggregation member according to an example embodiment;

FIGS. 6A and 6B are graphs illustrating aggregation of impurities in chemical liquid for semiconductor manufacturing; and

FIGS. 7A and 7B are graphs illustrating aggregation of impurities in chemical liquid for semiconductor manufacturing.

### DETAILED DESCRIPTION

Hereinafter, embodiments are described in detail with reference to the accompanying drawings. Identical reference numerals are used for the same constituent elements in the drawings, and duplicate descriptions thereof are omitted.

Embodiments described herein are example embodiments, and thus, the disclosure is not limited thereto.

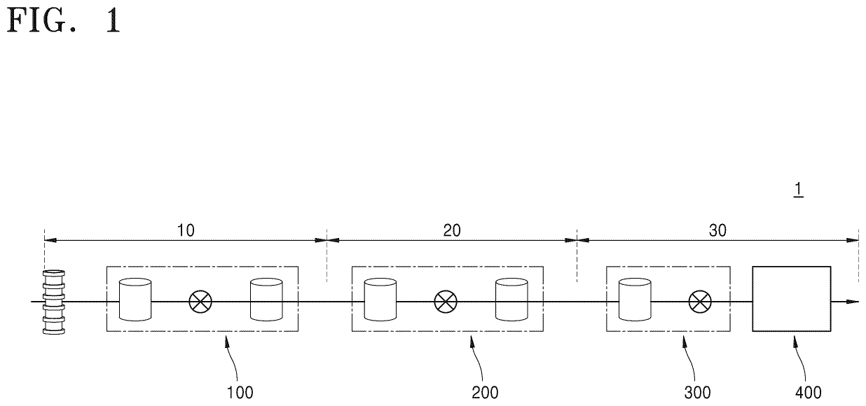

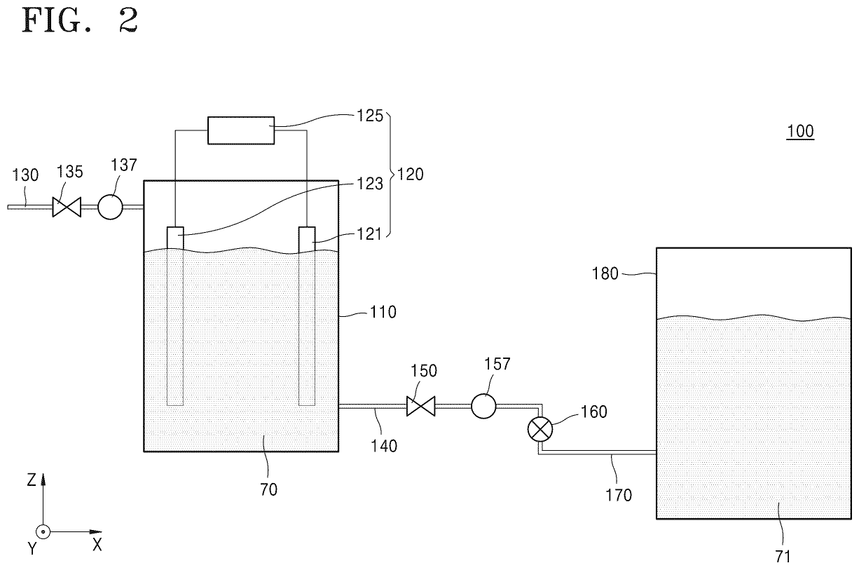

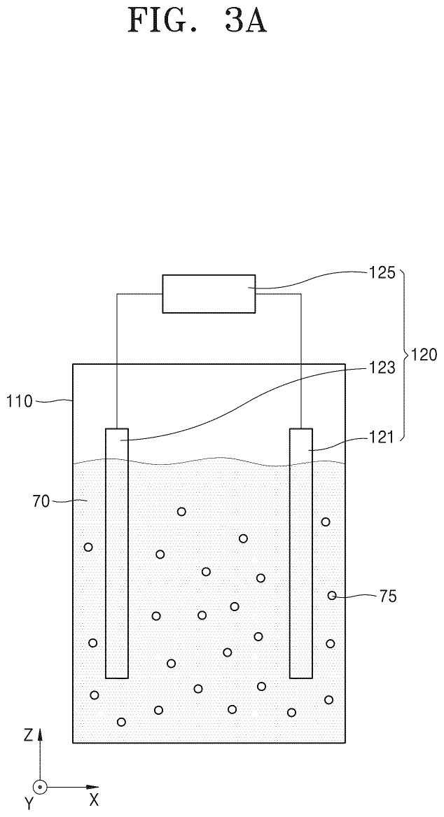

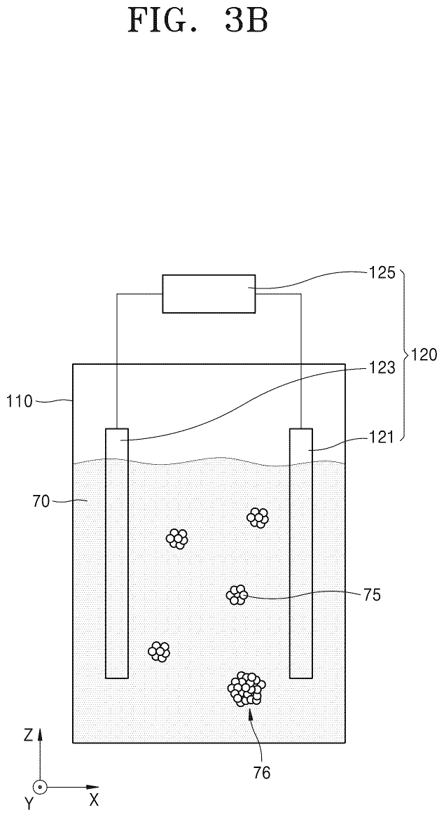

FIG. 1 is a diagram of a chemical liquid moving system for semiconductor manufacturing 1, according to an example embodiment. FIG. 2 is a diagram of chemical liquid purification apparatuses for semiconductor manufacturing 100, 200, and 300, according to an example embodiment. FIGS. 3A and 3B are diagrams illustrating an operation of the chemical liquid purification apparatus for semiconductor manufacturing 100 of FIG. 2.

Referring to FIGS. 1 through 3B, the chemical liquid moving system for semiconductor manufacturing 1 may include a manufacturing unit 10, a supply unit 20, and a processing unit 30. The manufacturing unit 10 may be configured to manufacture chemical liquid for semiconductor manufacturing 70. The chemical liquid for semiconductor manufacturing 70 may include a chemical liquid used in a semiconductor process. For example, the chemical liquid for semiconductor manufacturing 70 may include a chemical liquid used in a cleaning process, an exposure process, an etching process, a development process, a deposition process, or the like, and may include ultra-pure water (UPW), liquid or gaseous organic compounds, non-ionic liquids, etc. In addition, the chemical liquid for semiconductor manufacturing 70 may include a liquid containing at least one of hydrogen peroxide, sulfuric acid, phosphoric acid, hydrochloric acid, ammonium hydroxide, isopropyl alcohol (IPA), a thinner, tetramethyl ammonium hydroxide (TMAH), a developer, and a hydrofluoric acid. In some embodiments, the chemical liquid for semiconductor manufacturing may include a liquid photo-resist. However, the chemical liquid for semiconductor manufacturing 70 is not limited thereto, and the chemical liquid for semiconductor manufacturing 70 may be a chemical liquid used in the semiconductor manufacturing process, and any chemical liquid containing impurities 75 may be sufficient. In addition, impurities 75 may be in a dissolved state in the chemical liquid for semiconductor manufacturing 70, or may be in a form of particles. According to embodiments, the diameter of the impurities 75 included in the chemical liquid for semiconductor manufacturing 70 may be in a range of about 0.5 to about 20 nm. However, the diameter of the impurities 75 is not limited thereto.

The supply unit 20 may be configured to provide the chemical liquid for semiconductor manufacturing 70 manufactured by the manufacturing unit 10 to the processing unit 30. For example, the chemical liquid for semiconductor manufacturing 70 manufactured by the manufacturing unit 10 may be temporarily stored in the supply unit 20 before being provided to the processing unit 30. In addition, the supply unit 20 may provide additional processes on the chemical liquid for semiconductor manufacturing 70 manufactured by the manufacturing unit 10. The additional processes may include a chemical process and a physical process newly applied to the chemical liquid for semiconductor manufacturing 70.

The processing unit 30 may be configured to process a wafer by using the chemical liquid for semiconductor manufacturing 70 supplied by the supply unit 20. According to some embodiments, the processing unit 30 may perform a cleaning process, an etching process, a developing process, a deposition process, or the like on a wafer. Various processes on the wafer may be performed in a semiconductor equipment 400. The semiconductor equipment 400 may be configured to perform a process in a semiconductor or display manufacturing line.

According to some embodiments, the manufacturing unit 10, the supply unit 20, and the processing unit 30 may include semiconductor manufacturing chemical liquid purification apparatuses 100, 200, and 300, respectively. Because the semiconductor manufacturing chemical liquid purification apparatuses 100, 200, and 300 respectively provided to the manufacturing unit 10, the supply unit 20, and the processing unit 30 may be substantially the same as or similar to each other, hereinafter, the semiconductor manufacturing chemical liquid purification apparatus 100 provided to the manufacturing unit 10 is mainly described.

The semiconductor manufacturing chemical liquid purification apparatus 100 may include a first line 130, a first tank 110, an aggregation member 120, a second line 140, a filter 160, a second tank 180. The first line 130 may be configured to supply the semiconductor manufacturing chemical liquid 70 to the first tank 110. The first line 130 may provide a path for supplying the semiconductor manufacturing chemical liquid 70 manufactured by chemical liquid manufacturing equipment for semiconductor manufacturing to the first tank 110. The first line 130 may be physically connected to the first tank 110. In some embodiments, the first line 130 may be connected to an upper portion of the first tank 110.

The first tank 110 may be configured to store the chemical liquid for semiconductor manufacturing 70. The first tank 110 may be a tank for storing the chemical liquid for semiconductor manufacturing 70 to be purified, and may be configured to store liquid or a gas. For example, when a gas at relatively high pressure is stored, the first tank 110 may include a ball tank. For example, when liquid of volatility is stored, the first tank 110 may include a floating roof. According to some embodiments, the first tank 110 may be configured to accommodate all of a first electrode 121, a second electrode 123, and the chemical liquid for semiconductor manufacturing 70.

The first tank 110 may include an inlet port and an outlet port. The inlet port may be an inlet through which the chemical liquid for semiconductor manufacturing 70 flows in, and the outlet port may be an outlet through which the chemical liquid for semiconductor manufacturing 70 is exhausted. According to some embodiments, the inlet port may be connected to the first line 130, and the outlet port may be connected to the second line 140. According to some embodiments, one of the inlet port and the outlet port may be at the upper portion of the first tank 110, and the other may be at a lower portion of the first tank 110. According to some embodiments, the outlet port may be configured to switch between an off state in which the chemical liquid for semiconductor manufacturing 70 stored in the first tank 110 does not flow out through the second line 140, and an on state in which the chemical liquid for semiconductor manufacturing 70 flows out through the second line 140. According to some embodiments, the outlet port may maintain the off state while the chemical liquid for semiconductor manufacturing 70 in the first tank 110 is processed by the aggregation member 120. In addition, the outlet port may be switched to the on state, when the process on the chemical liquid for semiconductor manufacturing 70 by the aggregation member 120 is completed.

According to some embodiments, a first valve 135 and a first pump 137 may be arranged on the first line 130. The first valve 135 may be configured to control a flow of the chemical liquid for semiconductor manufacturing 70 flowing through the first line 130. For example, the first valve 135 may perform an on-off operation on the flow of the chemical liquid for semiconductor manufacturing 70 flowing through the first line 130. In addition, the first valve 135 may adjust the flow rate of the chemical liquid for semiconductor manufacturing 70 flowing through the first line 130. According to some embodiments, when a certain amount or more of the chemical liquid for semiconductor manufacturing 70 is stored in the first tank 110, the first valve 135 may be switched to the off state. Accordingly, the chemical liquid for semiconductor manufacturing 70 may no longer be supplied to the first tank 110. The first pump 137 may be configured to control a flow of the chemical liquid for semiconductor manufacturing 70 flowing through the first line 130. For example, the first pump 137 may adjust pressure in the first line 130 to control a flow of the chemical liquid for semiconductor manufacturing 70. The first pump 137 may perform an on-off operation on the flow of the chemical liquid for semiconductor manufacturing 70 flowing through the first line 130. In addition, the first pump 137 may adjust the flow rate of the chemical liquid for semiconductor manufacturing 70 flowing through the first line 130.

The aggregation member 120 may be configured to aggregate the impurities 75 contained in the chemical liquid for semiconductor manufacturing 70 stored in the first tank 110. The aggregation member 120 may be configured to aggregate each of the impurities 75 contained in the chemical liquid for semiconductor manufacturing 70 stored in the first tank 110. According to some embodiments, the aggregation member 120 may include the first electrode 121, the second electrode 123, and an alternating current (AC) waveform generator 125. According to some embodiments, the first electrode 121 and the second electrode 123 may be provided in the first tank 110. One of the first electrode 121 and the second electrode 123 may function as a cathode, and the other may function as an anode. In some embodiments, polarities of the first electrode 121 and the second electrode 123 may also vary according to process progression.

In some embodiments, the first electrode 121 and the second electrode 123 may be provided in a state of being spaced apart from each other in the first tank 110. The first electrode 121 and the second electrode 123 may extend in parallel with each other. In the following diagrams, a Z-axis direction may indicate a direction in which the first electrode 121 and the second electrode 123 extend, an X-axis direction and a Y-axis direction may indicate a direction in parallel with a plane perpendicular to the Z-axis direction, and the X-axis direction and the Y-axis direction may be directions perpendicular to each other.

In addition, in the following diagrams, a first horizontal direction may be understood as the X-axis direction, a second horizontal direction may be understood as the Y-axis direction, and a vertical direction may be understood as the Z-axis direction.

Each of the first electrode 121 and the second electrode 123 may be connected to the AC waveform generator 125. The AC waveform generator 125 may be provided to supply an AC to the first electrode 121 and the second electrode 123. However, in some embodiments, the AC waveform generator 125 may supply a direct current to the first electrode 121 and the second electrode 123 as necessary. According to some embodiments, the AC waveform generator 125 may apply a voltage in a range of about −5 V to about 5 V to each of the first electrode 121 and the second electrode 123. According to some embodiments, an output frequency of the AC waveform generator 125 may be in a range of about 1 kHz to about 1000 kHz.

When the AC waveform generator 125 supplies an AC to each of the first electrode 121 and the second electrode 123, a non-uniform electrical field may occur between the first electrode 121 and the second electrode 123. A non-uniform electrical field may apply dielectrophoretic force to permanent/induced dipoles of the impurities 75 contained in the chemical liquid for semiconductor manufacturing 70 stored in the first tank 110. Accordingly, the impurities 75 may be aggregated together as illustrated in FIG. 3B to form impurities lump 76. The impurities lump 76 may be formed as a plurality of impurities 75 are aggregated together.

When an AC voltage is applied to each of the first electrode 121 and the second electrode 123 by the AC waveform generator 125, an electrical field between the first electrode 121 and the second electrode 123 may be formed. In this case, because an AC voltage is applied to the first electrode 121 and the second electrode 123, a line of electric force may be induced from the second electrode 123 to the first electrode 121, or a line of electric force may be induced from the first electrode 121 to the second electrode 123. Accordingly, an electrical field having a non-uniform gradient may be generated between the first electrode 121 and the second electrode 123.

When a line of electric force is induced from the second electrode 123 to the first electrode 121, the line of electric force may be induced in a form of expanding from the second electrode 123 toward the first electrode 121. For example, the gradient of the electrical field near the second electrode 123 may be greater than the gradient of the electrical field near the first electrode 121. Accordingly, a relatively stronger electrical field may be formed on the second electrode 123, and a relatively weaker electrical field may be formed on the first electrode 121. Based on the gradient of non-uniform electrical field, the impurities 75 may be aggregated. For example, when the impurities 75 does not have a polarity, the impurities 75 may have an electrical dipole form due to a non-uniform electrical field. The magnitude and direction of the polarity induced by the impurities 75 may vary depending on the frequency of the electrical field, the chemical liquid for semiconductor manufacturing 70, and dielectric properties, such as conductivity and permittivity of each of the impurities 75. According to some embodiments, the diameter of the impurities lump 76 may be in a range of about 100 nm to about 1 μm. According to some embodiments, the diameter of the impurities lump 76 may be in a range of about 100 nm to about 5 μm.

According to some embodiments, when an electrical field is formed in the chemical liquid for semiconductor manufacturing 70 stored in the first tank 110 by the aggregation member 120, the impurities 75 may be aggregated together by the aggregation member 120 to form the impurities lump 76, and the impurities 75 may not be attached to surfaces of the first electrode 121 and the second electrode 123. The impurities lump 76, in which the impurities 75 are aggregated, may still drift off in the chemical liquid for semiconductor manufacturing 70.

The second line 140 may be configured to provide a path for the chemical liquid for semiconductor manufacturing 70 stored in the first tank 110 to move external to the first tank 110. The second line 140 may supply the chemical liquid for semiconductor manufacturing 70 stored in the first tank 110 to the outside of the first tank 110. Through the second line 140, the chemical liquid for semiconductor manufacturing 70 processed by the aggregation member 120 in the first tank 110 may be supplied.

According to some embodiments, the second line 140 may be configured to connect the first tank 110 to a third line 170. In some embodiments, at least one of a second valve 150 and a second pump 157 may be formed on the second line 140. The second valve 150 may be configured to control a flow of the chemical liquid for semiconductor manufacturing 70 flowing through the second line 140. For example, the second valve 150 may perform an on-off operation on the flow of the chemical liquid for semiconductor manufacturing 70 flowing through the second line 140. In addition, the second valve 150 may adjust the flow rate of the chemical liquid for semiconductor manufacturing 70 flowing through the second line 140. According to some embodiments, the second valve 150 may maintain an off state until processing of the chemical liquid for semiconductor manufacturing 70 by the aggregation member 120 in the first tank 110 is completed. In this case, the chemical liquid for semiconductor manufacturing 70 flowing along the second line 140 may not flow into the filter 160. The second valve 150 may maintain an on state when processing of the chemical liquid for semiconductor manufacturing 70 by the aggregation member 120 in the first tank 110 is completed. In this case, the chemical liquid for semiconductor manufacturing 70 flowing along the second line 140 may flow into the filter 160. As a result, the second valve 150 may introduce or block the chemical liquid for semiconductor manufacturing 70 into the filter 160. The second pump 157 may be configured to control a flow of the chemical liquid for semiconductor manufacturing 70 flowing through the second line 140. For example, the second pump 157 may control a flow of the chemical liquid for semiconductor manufacturing 70 by adjusting pressure in the second line 140. The second pump 157 may perform an on-off operation on the chemical liquid for semiconductor manufacturing 70 flowing through the second line 140. In addition, the second pump 157 may adjust the flow rate of the chemical liquid for semiconductor manufacturing 70 flowing through the second line 140.

According to some embodiments, the filter 160 may be provided in the second line 140. The filter 160 may be configured to filter the impurities lump 76 in the chemical liquid for semiconductor manufacturing 70 flowing through the second line 140. The filter 160 may include, for example, a point of use (POU) filter, a disposable filter, a bulk cartridge filter. According to some embodiments, the filter 160 may be replaced after a certain level or more of the impurities lump 76 is filtered.

According to some embodiments, a membrane may be formed inside the filter 160. The membrane may include, for example, a filtering membrane. A plurality of openings may be formed in the membrane. The size of the opening of the membrane may be in a range of about 2 nm to about 5 μm. The impurities lumps 76 included in the chemical liquid for semiconductor manufacturing 70 flowing through the second line 140 may be filtered by the membrane of the filter 160.

According to some embodiments, the filter 160 may include polypropylene (PP), polyethersulfone (PES), polyimide, polyethylene, ultra high molecular weight polyethylene (UPE), polytetrafluoroethylene (PTFE), polysulfone (PSF), nylon, etc.

The third line 170 may be configured to connect the second line 140 to the second tank 180. The chemical liquid for semiconductor manufacturing 70 having passed through the filter 160 may be supplied to the third line 170. There may be no impurities 75 in the chemical liquid for semiconductor manufacturing 70 to be supplied to the third line 170. The chemical liquid for semiconductor manufacturing 70 having moved along the second line 140 may pass through the filter 160 to have all of the impurities lumps 76 removed therefrom. Accordingly, there may be no impurities 75 in the chemical liquid for semiconductor manufacturing 70 to be supplied to the third line 170.

The second tank 180 may be configured to store purified chemical liquid for semiconductor manufacturing 71 which is connected to the third line 170. According to some embodiments, there may be no impurities 75 included in the purified chemical liquid for semiconductor manufacturing 71 stored in the second tank 180.

The impurities 75 contained in the chemical liquid for semiconductor manufacturing 70 may be removed by the filter 160. However, as the size of the impurities 75 gradually decreases, the opening of the membrane formed in the filter 160 gradually decreases, and particularly, when the impurities 75 has a diameter of nanometers, the size of the opening of the filter 160 is also required to be in nanometers. As a result, the chemical liquid for semiconductor manufacturing 70 may not easily pass through the filter 160 and be stagnated.

However, the chemical liquid purification apparatus for semiconductor manufacturing 100 may aggregate impurities 75 in the chemical liquid for semiconductor manufacturing 70 by using the aggregation member 120 to form the impurities lump 76, and filter the impurities lump 76 by using the filter 160 to provide the chemical liquid for semiconductor manufacturing 70, in which the impurities 75 has been removed therefrom. Accordingly, the opening size of the filter 160 may be formed relatively larger, and a phenomenon, in which the chemical liquid for semiconductor manufacturing 70 passing through the filter 160 is stagnated, may be prevented.

In addition, because the aggregation member 120 aggregates the impurities 75 by using a dielectrophoresis phenomenon, impurities 75 in nanometers (nm) may also be aggregated.

Furthermore, the aggregation member 120 and the filter 160 may be formed in an area other than the first tank 110. According to some embodiments, aggregation member 120 and the filter 160 may be formed in a pipe line providing a path for the chemical liquid for semiconductor manufacturing 70 to move. For example, the aggregation member 120 and the filter 160 may be formed in at least one of the first line 130 and the second line 140. Accordingly, an aggregation of the impurities 75 may occur in at least one line among the first line 130 and the second line 140, and the aggregated impurities lump 76 may be filtered by the filter 160 formed on the at least one line. Accordingly, the chemical liquid for semiconductor manufacturing 70 not including the impurities 75 may be provided.

In addition, the aggregation member 120 and the filter 160 may be formed even in the semiconductor equipment 400. For example, the aggregation member 120 and the filter 160 formed in the semiconductor equipment 400 may aggregate the impurities 75 in the chemical liquid for semiconductor manufacturing 70 to form the impurities lump 76 before the chemical liquid for semiconductor manufacturing 70 is introduced onto a wafer, and the filter 160 may remove the impurities lump 76. Accordingly, the impurities 75 included in the chemical liquid for semiconductor manufacturing 70 introduced onto a wafer may be reduced.

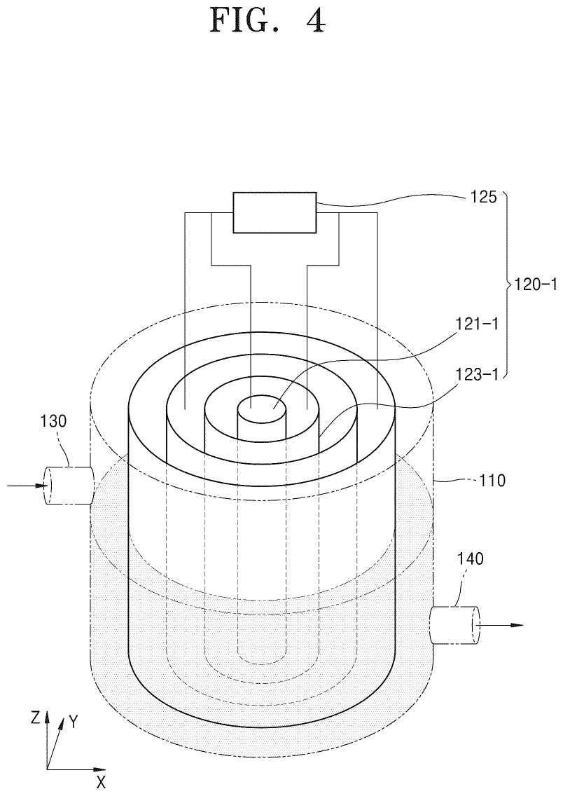

FIG. 4 is a schematic perspective view of an aggregation member 120-1 according to an embodiment. Hereinafter, duplicate descriptions given with reference to FIGS. 1 through 3B are omitted and differences are mainly described.

Referring to FIG. 4, the aggregation member 120-1 may include a first electrode 121_1, a second electrode 123_1, and the AC waveform generator 125. The first electrode 121_1 and the second electrode 123_1 may be included in the first tank 110. The first tank 110 may be connected to each of the first line 130 and the second line 140. In the first tank 110, the chemical liquid for semiconductor manufacturing 70 supplied through the first line 130 may be stored.

According to some embodiments, each of the first electrode 121_1 and the second electrode 123_1 may be provided in plurality. The first electrodes 121_1 and the second electrodes 123_1 may each have a hollow cylinder form and may be alternately arranged. For example, the first electrodes 121_1 and the second electrodes 123_1 may be arranged with different curvature radii from each other, and may be alternately arranged. In some embodiments, the first electrode 121_1 may extend in a curved manner while maintaining a certain distance from the second electrode 123_1 adjacent thereto.

In some embodiments, at least one first electrode 121_1 may be between two second electrodes 123_1. For example, at least one first electrode 121_1 may face any one second electrode 123_1 from one surface of the first electrode 121_1, and may face another second electrode 123_1 from another surface of the first electrode 121_1. In some embodiments, at least one second electrode 123_1 may face any one first electrode 121_1 from one surface of the second electrode 123_1, and may face another first electrode 121_1 from another surface opposite to the one surface of the second electrode 123_1.

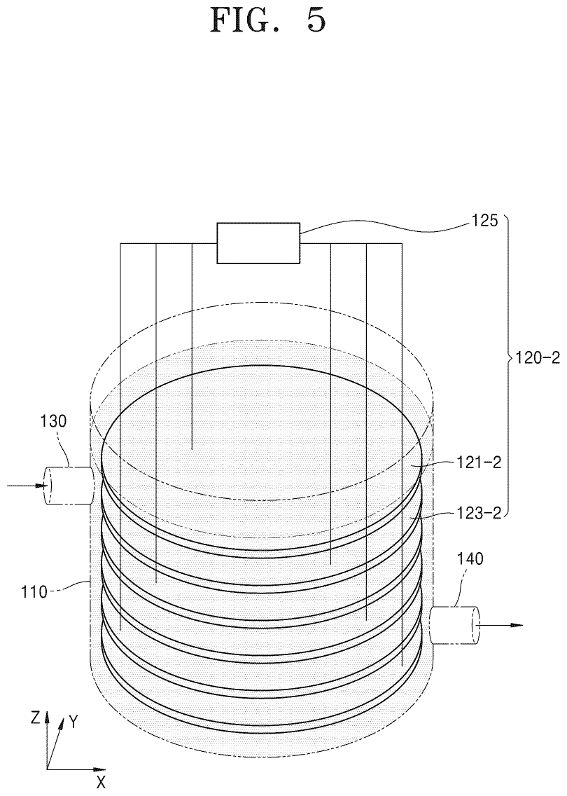

FIG. 5 is a schematic perspective view of an aggregation member 123-2 according to an embodiment. Hereinafter, duplicate descriptions given with reference to FIGS. 1 through 4 are omitted and differences are mainly described.

Referring to FIG. 5, the aggregation member 120-2 may include a first electrode 121_2, a second electrode 123_2, and the AC waveform generator 125. The first electrode 121_2 and the second electrode 123_2 may be included in the first tank 110. The first tank 110 may be connected to each of the first line 130 and the second line 140. In the first tank 110, the chemical liquid for semiconductor manufacturing 70 supplied through the first line 130 may be stored.

According to some embodiments, each of the first electrode 121_2 and the second electrode 123_2 may be provided in plurality. The first electrodes 121_2 and the second electrodes 1232 may each have a flat plate shape. For example, the first electrodes 121_2 and the second electrodes 123_2 may have a shape extending in parallel with each other. According to some embodiments, the first electrode 121_2 and the second electrode 123_2 may be alternately arranged in a vertical direction Z. The first electrode 121_2 and the second electrode 123_2 may be arranged to face each other in the vertical direction Z.

In some embodiments, the second electrode 123_2 may be arranged at each of an upper portion and a lower portion of at least one first electrode 121_2. In addition, the first electrode 121_2 may be arranged at each of an upper portion and a lower portion of at least one second electrode 123_2 in the vertical direction Z. According to some embodiments, the first electrode 121_2 and the second electrode 123_2 may face each other at the same distance.

In addition, in some embodiments, a plurality of first electrodes 121_2 and a plurality of second electrodes 123_2 may be alternately arranged in a horizontal direction. For example, each of the first electrodes 121-2 and the second electrodes 123-2 may have a flat plate shape extending in the vertical direction Z, and may be alternately arranged in the horizontal direction. Accordingly, the first electrode 121_2 and the second electrode 123_2 may be arranged to face each other in the horizontal direction.

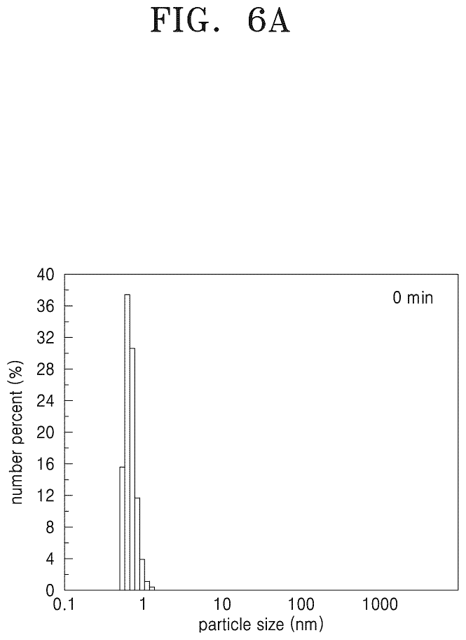

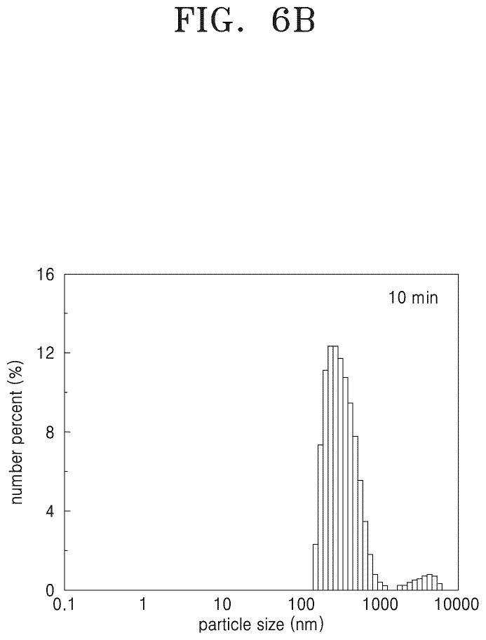

FIGS. 6A and 6B are graphs illustrating aggregation of the impurities 75 and the impurities lump 76 in the chemical liquid for semiconductor manufacturing 70, respectively. Hereinafter, duplicate descriptions given with reference to FIGS. 1 through 3B are omitted.

Referring to FIGS. 3A, 3B, 6A, and 6B, the chemical liquid for semiconductor manufacturing 70 stored in the first tank 110 may be processed by the aggregation member 120. Before the aggregation member 120 processes the chemical liquid for semiconductor manufacturing 70, the diameter of the impurities 75 in the chemical liquid for semiconductor manufacturing 70 may be in the range of about 0.5 nm to about 2 nm. In some embodiments, the chemical liquid for semiconductor manufacturing 70 experimented and illustrated in FIGS. 6A and 6B may include a solution containing nitric acid and hydrofluoric acid. In addition, the volume of the chemical liquid for semiconductor manufacturing 70 may be in a range of about 10 mL to about 100 mL. However, the chemical liquid for semiconductor manufacturing 70 is not limited thereto.

When the AC waveform generator 125 of the aggregation member 120 supplies an AC to each of the first electrode 121 and the second electrode 123, impurities 75 in the chemical liquid for semiconductor manufacturing 70 may be aggregated due to dielectrophoresis phenomenon. In this case, the diameter of the impurities lump 76 formed by aggregation of the impurities 75 may be in the range of about 100 nm to about 10000 nm, as illustrated in FIG. 6B. In particular, most of the impurities lump 76 aggregated by the aggregation member 120 may have a diameter of about 100 nm to about 1000 nm. In this case, about 10 minutes may be required for the impurities 75 to aggregate into the impurities lump 76. In some embodiments, the AC waveform generator 125 may apply a voltage in a range of about −5 V to about 5 V to each of the first electrode 121 and the second electrode 123. An output frequency of the AC waveform generator 125 may be in a range of about 1 kHz to about 1000 kHz.

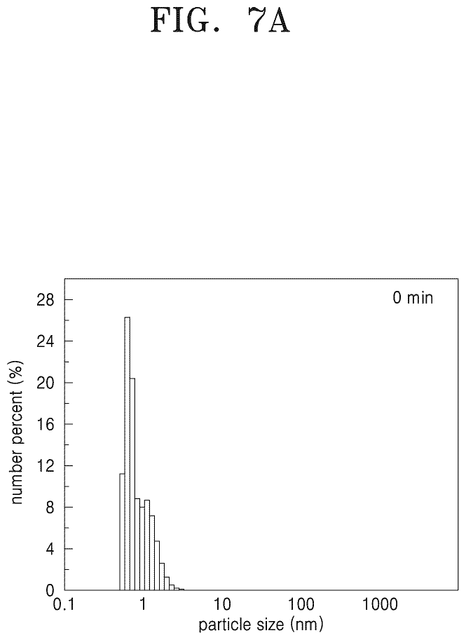

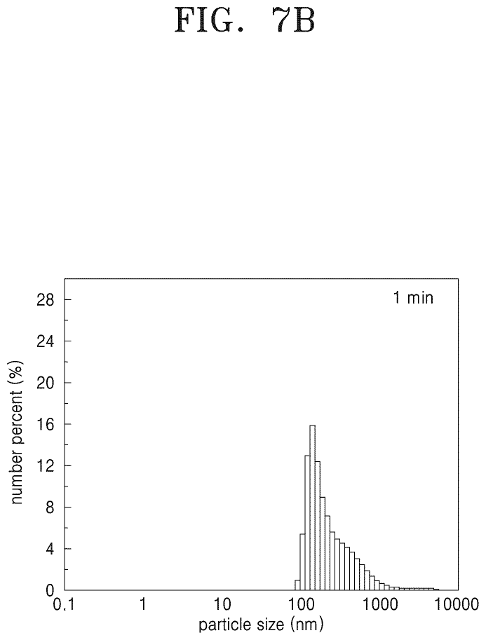

FIGS. 7A and 7B are graphs illustrating aggregation of the impurities 75 and the impurities lump 76 included in the chemical liquid for semiconductor manufacturing 70, respectively. Hereinafter, duplicate descriptions given with reference to FIGS. 1 through 3B are omitted.

Referring to FIGS. 3A, 3B, 7A, and 7B, the chemical liquid for semiconductor manufacturing 70 stored in the first tank 110 may be processed by the aggregation member 120. Before the aggregation member 120 processes the chemical liquid for semiconductor manufacturing 70, the diameter of the impurities 75 in the chemical liquid for semiconductor manufacturing 70 may be in the range of about 0.5 nm to about 5 nm. In some embodiments, the chemical liquid for semiconductor manufacturing 70 experimented and illustrated in FIGS. 7A and 7B may include a solution containing silicate. In addition, the volume of the chemical liquid for semiconductor manufacturing 70 may be in a range of about 10 mL to about 100 mL. However, the chemical liquid for semiconductor manufacturing 70 is not limited thereto.

When the AC waveform generator 125 of the aggregation member 120 supplies an AC to each of the first electrode 121 and the second electrode 123, impurities 75 in the chemical liquid for semiconductor manufacturing 70 may be aggregated due to dielectrophoresis phenomenon. In this case, the diameter of the impurities lump 76 formed by aggregation of the impurities 75 may be in the range of about 100 nm to about 10000 nm, as illustrated in FIG. 7B. For example, most of the impurities lump 76 aggregated by the aggregation member 120 may have a diameter of about 100 nm to about 1000 nm. About 10 minutes may be required for the impurities 75 to aggregate into the impurities lump 76. In some embodiments, the AC waveform generator 125 may apply a voltage in a range of about-5 V to about 5 V to each of the first electrode 121 and the second electrode 123. An output frequency of the AC waveform generator 125 may be in a range of about 1 kHz to about 1000 kHz.

While embodiments have been described with reference to the figures, it will be understood by those of ordinary skill in the art that various changes in form and details may be made therein without departing from the spirit and scope as defined by the following claims and their equivalents.

What is claimed is:

1. A chemical liquid purification apparatus for semiconductor manufacturing, the apparatus comprising:
a first tank configured to store chemical liquid, the chemical liquid comprising impurities;
a first line configured to supply the chemical liquid to the first tank;
a first electrode and a second electrode included in the first tank;
an alternating current waveform generator connected to the first electrode and the second electrode;
a second line configured to supply the chemical liquid processed in the first tank to an outside of the first tank; and
a filter configured to filter the impurities in the chemical liquid flowing in the second line.

2. The apparatus of claim 1, wherein a diameter of the impurities in the chemical liquid supplied into the first tank in the first line is in a range of 0.5 nm to 20 nm, and
wherein a diameter of the impurities in the chemical liquid flowing in the second line is in a range of 100 nm to 5 μm.

3. The apparatus of claim 1, wherein the chemical liquid comprises at least one of hydrogen peroxide, sulfuric acid, phosphoric acid, hydrochloric acid, ammonium hydroxide, isopropyl alcohol, a thinner, tetramethyl ammonium hydroxide, a developer, and hydrofluoric acid.

4. The apparatus of claim 1, wherein the first electrode comprises a plurality of first electrodes and the second electrode comprises a plurality of second electrodes,
wherein the plurality of first electrodes and the plurality of second electrodes have a cylinder shape, and
wherein the plurality of first electrodes and the plurality of second electrodes are alternately disposed in a horizontal direction.

5. The apparatus of claim 1, wherein the first electrode comprises a plurality of first electrodes and the second electrode comprises a plurality of second electrodes,
wherein the plurality of first electrodes and the plurality of second electrodes have a flat plate shape, and
wherein the plurality of first electrodes and the plurality of second electrodes are alternately disposed.

6. The apparatus of claim 1, wherein the alternating current waveform generator is further configured to apply a voltage in a range of −5 V to 5 V to the first electrode and the second electrode.

7. The apparatus of claim 1, wherein an output frequency of the alternating current waveform generator is in a range of 1 kHz to 1000 kHz.

8. The apparatus of claim 1, further comprising at least one of a valve and a pump configured to adjust a flow of the chemical liquid flowing in the second line.

9. The apparatus of claim 1, wherein at least one membrane is included in the filter, and
wherein a size of an opening of the membrane is in a range of 2 nm to 5 μm.

10. The apparatus of claim 1, wherein the impurities are dissolved in the chemical liquid.

11. A chemical liquid purification apparatus for semiconductor manufacturing, the apparatus comprising:
a first tank configured to store chemical liquid, the chemical liquid comprising impurities;
a first line configured to supply the chemical liquid to the first tank;
a first valve and a first pump configured to adjust a flow rate of the chemical liquid flowing in the first line;
a first electrode and a second electrode provided apart from each other in the first tank;
an alternating current waveform generator configured to provide an alternating current to the first electrode and the second electrode;
a second line configured to supply the chemical liquid processed in the first tank to an outside of the first tank; and
a second valve and a second pump configured to adjust a flow rate of the chemical liquid flowing in the second line;
a filter configured to filter the impurities in the chemical liquid flowing in the second line;
a third line connected to the second line; and
a second tank connected to the third line.

12. The apparatus of claim 11, wherein a diameter of the impurities in the chemical liquid supplied into the first tank in the first line is in a range of 0.5 nm to 20 nm, and
wherein a diameter of the impurities in the chemical liquid flowing into the second tank is in a range of 100 nm to 5 μm.

13. The apparatus of claim 11, wherein the filter comprises at least one of polypropylene, polyethersulfone, polyimide, polyethylene, ultra high molecular weight polyethylene, polytetrafluoroethylene, polysulfone, and nylon.

14. The apparatus of claim 11, wherein the first electrode comprises a plurality of first electrodes and the second electrode comprises a plurality of second electrodes, and
wherein the plurality of first electrodes and the plurality of second electrodes have a cylinder shape, and
wherein the plurality of first electrodes and the plurality of second electrodes are alternately disposed in a horizontal direction.

15. The apparatus of claim 11, wherein the first electrode comprises a plurality of first electrodes and the second electrode comprises a plurality of second electrodes,
wherein the plurality of first electrodes and the plurality of second electrodes have a flat plate shape, and
wherein the plurality of first electrodes and the plurality of second electrodes are alternately disposed.

16. The apparatus of claim 11, wherein the alternating current waveform generator is further configured to apply a voltage in a range of −5 V to 5 V to each of the first electrode and the second electrode.

17. The apparatus of claim 11, wherein an output frequency of the alternating current waveform generator is in a range of 1 kHz to 1000 kHz.

18. A chemical liquid purification apparatus for semiconductor manufacturing, the apparatus comprising:
a first tank configured to store chemical liquid, the chemical liquid comprising impurities;
a first line configured to supply the chemical liquid to the first tank;
a first valve and a first pump configured to adjust a flow rate of the chemical liquid flowing in the first line;
a first electrode and a second electrode spaced apart from each other in the first tank;
an alternating current waveform generator configured to provide an alternating current to the first electrode and the second electrode;
a second line configured to supply the chemical liquid processed in the first tank to an outside of the first tank; and
a second valve and a second pump configured to adjust a flow rate of the chemical liquid flowing in the second line;
a filter configured to filter the impurities in the chemical liquid flowing in the second line;
a third line connected to the second line; and
a second tank connected to the third line,
wherein a diameter of the impurities in the chemical liquid supplied into the first tank in the first line is in a range of 0.5 nm to 20 nm,
wherein a diameter of the impurities in the chemical liquid flowing into the second tank is in a range of 100 nm to 5 μm, and
wherein the alternating current waveform generator is further configured to apply a voltage in a range of −5 V to 5 V to the first electrode and the second electrode, and an output frequency of the alternating current waveform generator is in a range of 1 kHz to 1000 kHz.

19. The apparatus of claim 18, wherein at least one membrane is included in the filter, and
wherein a size of an opening of the membrane is in a range of 2 nm to 5 μm.

20. The apparatus of claim 18, wherein the chemical liquid comprises at least one of hydrogen peroxide, sulfuric acid, phosphoric acid, hydrochloric acid, ammonium hydroxide, isopropyl alcohol, a thinner, tetramethyl ammonium hydroxide, a developer, and hydrofluoric acid.
